(19) United States
(12) Patent Application Publication
(10) Pub. No.: US 2007/0029667 A1
(43) Pub. Date: Feb. 8, 2007

(54) SEMICONDUCTOR DEVICE

(75) Inventors: Tomoharu Fujii, Nagano-shi, Nagano (JP); Tomoki Kobayashi, Nagano-shi, Nagano (JP)

Correspondence Address: RANKIN, HILL, PORTER & CLARK LLP, 4080 ERIE STREET, WILLOUGHBY, OH, 44094-7836, US

(73) Assignee: SHINKO ELECTRIC INDUSTRIES CO., LTD., Nagano-shi (JP)

(21) Appl. No.: 11/462,188

(22) Filed: Aug. 3, 2006

(30) Foreign Application Priority Data
Aug. 5, 2005 (JP) 2005-227639

(51) Int. Cl. H01L 23/34

(52) U.S. Cl. 257/723

(57) ABSTRACT

A wiring substrate 11 having a power feeding layer 24 and a ground conductive layer 27 is provided, and also an inverted F-type antenna 20 is provided on a sealing resin 17, which covers a semiconductor chip 12 and a chip parts 13 connected to the wiring substrate 11, and an inverted F-type antenna 20 is connected electrically to the power feeding layer 24 and the ground conductive layer 27.

### TECHNICAL FIELD

The present disclosure relates to a semiconductor device and, more particularly, a semiconductor device having a passive circuit connected electrically to a ground conductive layer.

### RELATED ART

Among the semiconductor devices, there are some semiconductor devices each having the antenna as the passive circuit. Such semiconductor devices are employed as the wireless module, for example. Also, the chip antenna, the antenna pattern, or the like is employed as the antenna.

FIG. 21 is a sectional view of the semiconductor device having the chip antenna in the related art.

As shown in FIG. 21, a semiconductor device 100 has a wiring substrate 101, a semiconductor chip 102, an RF device 103, a chip antenna 104, and a component 105 for matching. A wiring pattern (not shown) is formed on the wiring substrate 101. The CPU semiconductor chip 102, the RF device 103, the chip antenna 104, and the component 105 for matching are provided on the wiring substrate 101, and connected electrically to wiring patterns (not shown) formed on the wiring substrate 101. Also, the component 105 for matching is connected electrically to the RF device 103 and the chip antenna 104 via the wiring pattern (not shown) formed on the wiring substrate 101.

FIG. 22 is a sectional view of a semiconductor device having an antenna pattern in the related art. In FIG. 22, the same reference symbols are affixed to the same constituent parts as those of the semiconductor device 100 shown in FIG. 21.

As shown in FIG. 22, a semiconductor device 110 has the wiring substrate 101, the CPU semiconductor chip 102, the RF device 103, and an antenna pattern 111. The CPU semiconductor chip 102 and the RF device 103 are provided on the wiring substrate 101. The antenna pattern 111 is formed on the wiring substrate 101. The antenna pattern 111 is connected electrically to the CPU semiconductor chip 102 and the RF device 103 via wiring patterns (not shown) formed on the wiring substrate 101 (see Patent Literature 1: Japanese Patent Unexamined Publication No. 2004-22667, for example).

As the antenna pattern 111, for example, the inverted F-type antenna is employed. The inverted F-type antenna is connected electrically to the ground conductive layer and the power-supply conductive layer (both not shown), and has been developed for the purpose of size reduction.

Also, with the progress of the recent CMOS technology, the CPU and the RF device can be manufactured on one semiconductor chip. Then, there is the semiconductor device that intends to achieve a side reduction by providing this structure onto the wiring substrate 101.

However, since the chip antenna 104 is expensive in the semiconductor device 100, there is such a problem that a cost of the semiconductor device 100 is increased.

Also, when the chip antenna 104 is employed, the component 105 for matching must be provided to adjust an impedance. Therefore, a size of the wiring substrate 101 along the surface direction is increased, and thus there were such problems that a cost of the semiconductor device 100 is increased and also a size of the semiconductor device 100 cannot be reduced.

In the semiconductor device 110, in order to form the antenna pattern 111, a region that is larger than a formation region of the chip antenna 104 is needed on the wiring substrate 101. Therefore, a size of the wiring substrate 101 along the surface direction is increased, and thus there were such problems that a cost of the semiconductor device 110 is increased and also a size of the semiconductor device 110 cannot be reduced.

Also, when the inverted F-type antenna is employed as the antenna pattern 111, the ground conductive layer (not shown) with a predetermined area must be provided onto the wiring substrate 101. Therefore, a size of the wiring substrate 101 along the surface direction is increased, and thus there were such problems that a cost of the semiconductor device 110 is increased and also a size of the semiconductor device 110 cannot be reduced.

In addition, in the case of the semiconductor device having the semiconductor chip to which both functions of the CPU and the RF device are provided, the formation regions of the CPU semiconductor chip 102 and the RF device 103 can be reduced. But there was such a problem that it is difficult to miniaturize satisfactorily the semiconductor device.

### SUMMARY

Embodiments of the present invention provide a semiconductor device capable of reducing a size and also reducing a cost.

According to a first aspect of one or more embodiments of the invention, a semiconductor device comprises: a wiring substrate; an electronic parts provided on a first main surface of the wiring substrate and connected electrically to the wiring substrate; a passive circuit; and a sealing resin for sealing the electronic parts; wherein the passive circuit is provided on the sealing resin, and a ground conductive layer is provided in an inside of the wiring substrate or on a second main surface on an opposite side to the first main surface of the wiring substrate.

According to the first aspect of one or more embodiments of the invention, since the passive circuit is provided on the sealing resin, and the ground conductive layer is provided in the inside of the wiring substrate or on the second main surface on the opposite side to the first main surface of the wiring substrate, a size of the wiring substrate along the surface direction can be reduced small rather than the related-art semiconductor device in which the ground conductive layer is provided to the first main surface of the wiring substrate. As a result, a size of the semiconductor device can be reduced and also a cost of the semiconductor device can be reduced.

According to a second aspect of one or more embodiments of the invention, a semiconductor device comprises: a wiring substrate; an electronic parts provided on a first main surface of the wiring substrate and connected electrically to the wiring substrate; a passive circuit; and a sealing resin for sealing the electronic parts; wherein a ground conductive layer is provided on the sealing resin, an insulating layer is provided on the ground conductive layer, and the passive circuit is provided on the insulating layer.

According to the second aspect of one or more embodiments of the invention, since the ground conductive layer is provided on the sealing resin, the insulating layer is provided on the ground conductive layer, and the passive circuit connected electrically to the ground conductive layer is provided on the insulating layer, a size of the wiring substrate along the surface direction can be reduced small rather than the related-art semiconductor device where the ground conductive layer is provided on the first main surface of the wiring substrate. As a result, a size of the semiconductor device can be reduced and also a cost of the semiconductor device can be reduced.

Various implementations may include one or more the following advantages. For example, a size of the semiconductor device can be reduced and also a cost of the semiconductor device can be reduced.

Other features and advantages may be apparent from the following detailed description, the accompanying drawings and the claims.

### BRIEF DESCRIPTION OF THE DRAWINGS

FIG. 1 is a sectional view of a semiconductor device according to a first embodiment of the present invention.

FIG. 2 is a view explaining an inverted F-type antenna.

FIG. 3 is a plan view of a core substrate on which semiconductor devices of the present embodiment are formed.

FIG. 4 is a view (#1) showing steps of manufacturing a semiconductor device according to a first embodiment.

FIG. 5 is a view (#2) showing steps of manufacturing the semiconductor device according to the first embodiment.

FIG. 6 is a view (#3) showing steps of manufacturing the semiconductor device according to the first embodiment.

FIG. 7 is a view (#4) showing steps of manufacturing the semiconductor device according to the first embodiment.

FIG. 8 is a view (#5) showing steps of manufacturing the semiconductor device according to the first embodiment.

FIG. 9 is a view (#6) showing steps of manufacturing the semiconductor device according to the first embodiment.

FIG. 10 is a view (#7) showing steps of manufacturing the semiconductor device according to the first embodiment.

FIG. 11 is a view (#8) showing steps of manufacturing the semiconductor device according to the first embodiment.

FIG. 12 is a view (#9) showing steps of manufacturing the semiconductor device according to the first embodiment.

FIG. 13 is a view (#10) showing steps of manufacturing the semiconductor device according to the first embodiment.

FIG. 16 is a view (#11) showing steps of manufacturing the semiconductor device according to the first embodiment.

FIG. 15 is a view (#12) showing steps of manufacturing the semiconductor device according to the first embodiment.

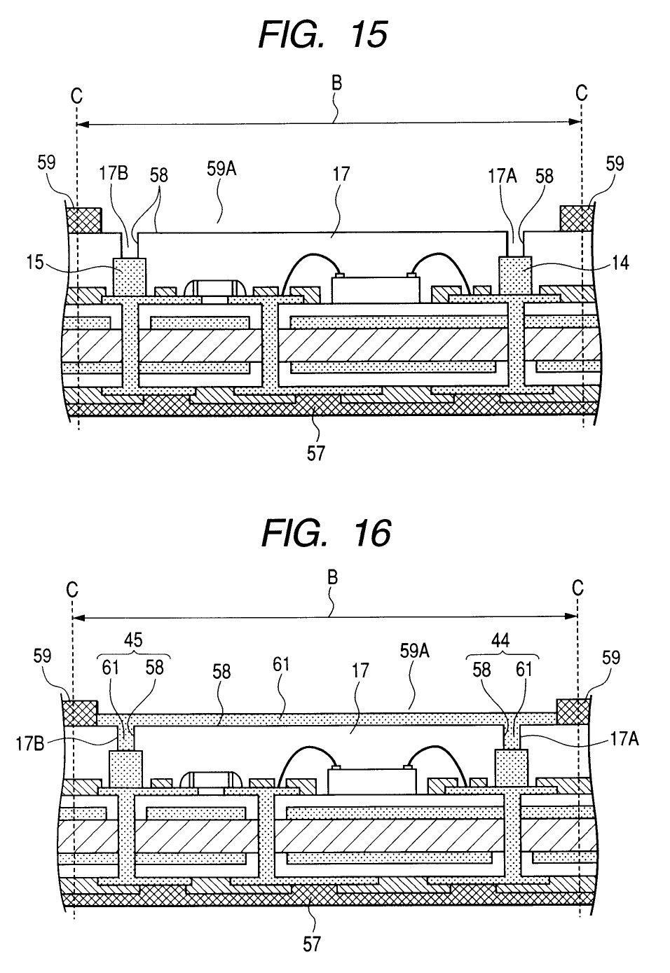

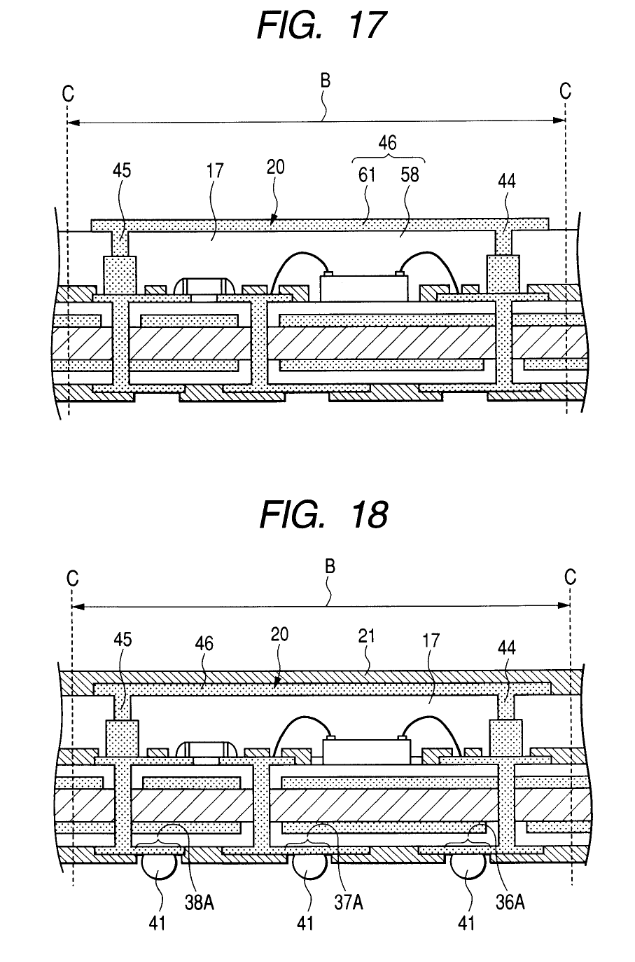

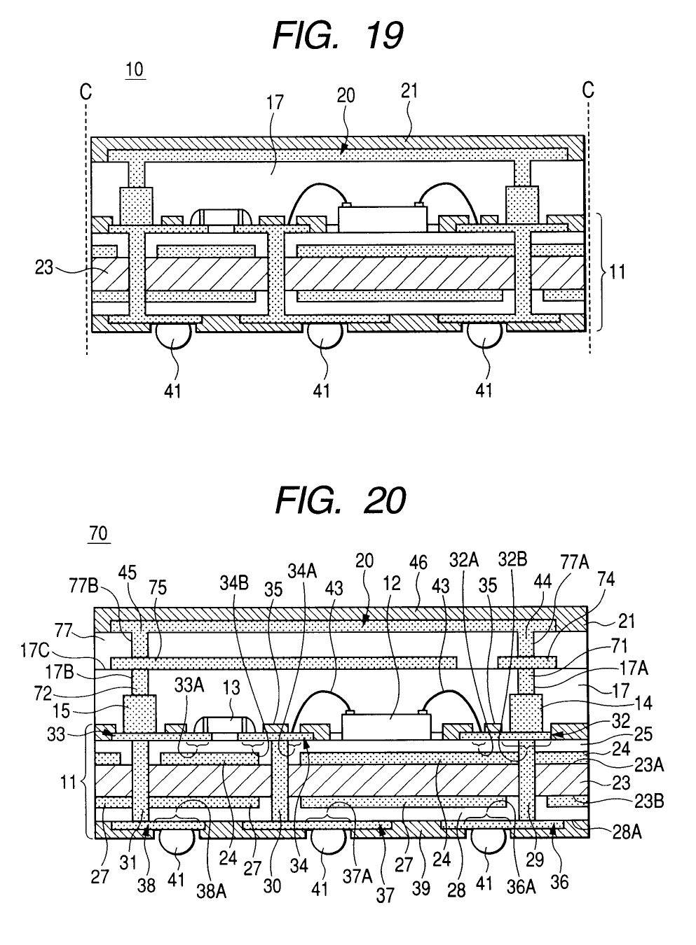

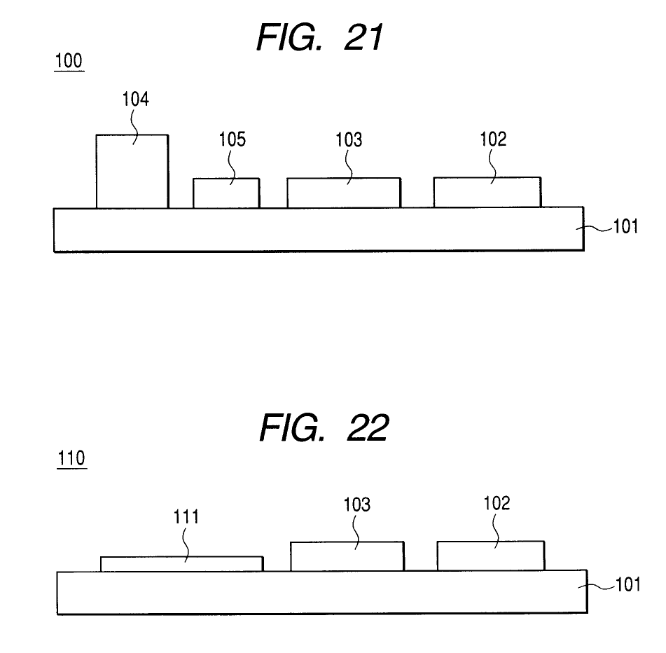

FIG. 16 is a view (#13) showing steps of manufacturing the semiconductor device according to the first embodiment.

FIG. 17 is a view (#14) showing steps of manufacturing the semiconductor device according to the first embodiment.

FIG. 18 is a view (#15) showing steps of manufacturing the semiconductor device according to the first embodiment.

FIG. 19 is a view (#16) showing steps of manufacturing the semiconductor device according to the first embodiment.

FIG. 20 is a sectional view of a semiconductor device according to a second embodiment of the present invention.

FIG. 21 is a sectional view of a semiconductor device having a chip antenna in the related art.

FIG. 22 is a sectional view of a semiconductor device having an antenna pattern in the related art.

### DETAILED DESCRIPTION

Next, embodiments of the present invention will be explained with reference to the drawings hereinafter.

### First Embodiment

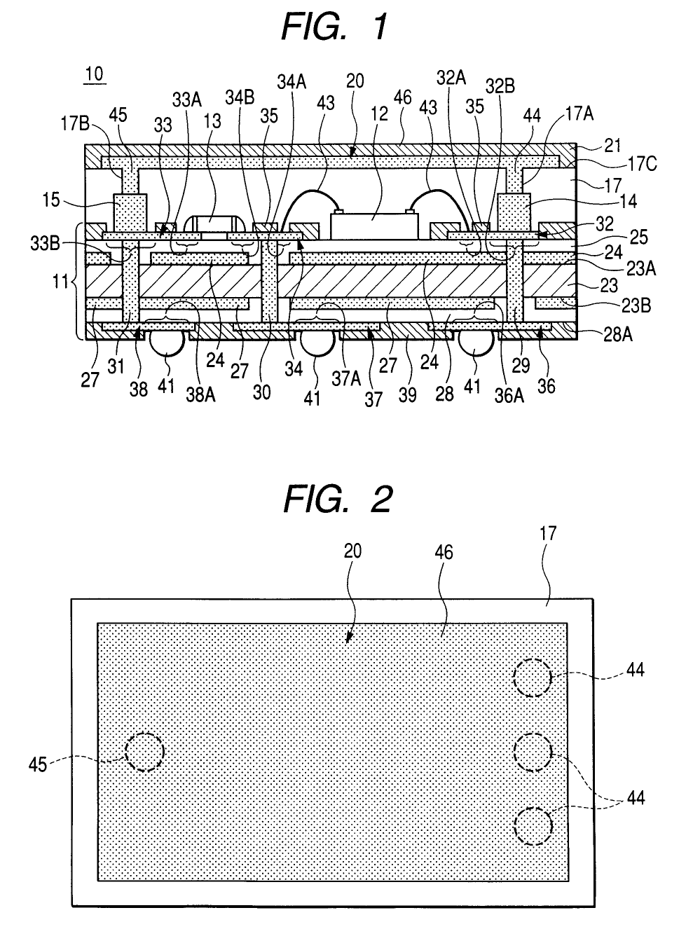

FIG. 1 is a sectional view of a semiconductor device according to a first embodiment of the present invention.

A semiconductor device 10 according to the first embodiment of the present invention will be explained with reference to FIG. 1 hereunder. In the present embodiment, following explanation will be made by taking as an example the case where an inverted F-type antenna 20 is employed as the passive circuit.

A semiconductor device 10 includes a wiring substrate 11, a semiconductor chip 12 and a chip parts 13 as the electronic parts, terminals 14, 15, a sealing resin 17, an inverted F-type antenna 20, and a protective film 21.

The wiring substrate 11 has a core substrate 23, a power-supply conductive layer 24, an upper resin layer 25, a ground conductive layer 27, a lower resin layer 28, through vias 29 to 31, upper wirings 32 to 34, protective films 35, 39, lower wirings 36 to 38, and external connection terminals 41.

The core substrate 23 is formed like a plate. As the core substrate 23, a glass epoxy substrate, a ceramic substrate, or the like, for example, may be employed. The power-supply conductive layer 24 is provided on an upper surface 23A of the core substrate 23. The power-supply conductive layer 24 is connected to the through via 29. As the material of the power-supply conductive layer 24, a conductive metal can be employed and concretely Cu, for example, can be employed.

The upper resin layer 25 is provided on the upper surface 23A of the core substrate 23 to cover the power-supply conductive layer 24. As the upper resin layer 25, for example, an epoxy-based resin can be employed.

The ground conductive layer 27 is set to a ground potential and is provided on a lower surface 23B of the core substrate 23. The ground conductive layer 27 is connected electrically to the through via 31. The ground conductive layer 27 is a ground conductive layer that is connected electrically to the inverted F-type antenna 20.

In this manner, since the ground conductive layer 27 that is connected electrically to the inverted F-type antenna 20 is provided to the inside of the wiring substrate 11, a size of the wiring substrate 11 along the surface direction can be reduced small rather than the related-art semiconductor device in which the ground conductive layer is provided to the first main surface (surface to which the semiconductor chip 12 and the chip parts 13 are connected) of the wiring substrate 11. Therefore, a size of the semiconductor device 10 can be reduced and also a cost of the semiconductor device 10 can be reduced.

Also, a layout of the wirings (e.g., the upper wirings 32, 33, etc.) formed on the wiring substrate 11 can be changed by utilizing the area of the wiring substrate 11 in which the ground conductive layer 27 is formed in the related art. As a result, flexibility of design can be increased.

As the material of the ground conductive layer 27, a conductive metal can be employed and concretely Cu, for example, can be employed.

The lower resin layer 28 is provided on the lower surface 23B of the core substrate 23 to cover the ground conductive layer 27. As the lower resin layer 28, for example, an epoxy-based resin can be employed.

The through via 29 is provided to pass through the core substrate 23, the power-supply conductive layer 24, the upper resin layer 25, and the lower resin layer 28 positioned between the upper wiring 32 and the lower wiring 36. The through via 29 is connected electrically to the power-supply conductive layer 24, the upper wiring 32, and the lower wiring 36.

The through via 30 is provided to pass through the core substrate 23, the upper resin layer 25, and the lower resin layer 28 positioned between the upper wiring 34 and the lower wiring 37. The through via 30 is connected electrically to the upper wiring 34 and the lower wiring 37.

The through via 31 is provided to pass through the core substrate 23, the ground conductive layer 27, the upper resin layer 25, and the lower resin layer 28 positioned between the upper wiring 33 and the lower wiring 38. The through via 31 is connected electrically to the ground conductive layer 27, the upper wiring 33, and the lower wiring 38. As the material of the through vias 29 to 31, a conductive metal can be employed and concretely Cu, for example, can be employed.

The upper wiring 32 is provided on a portion of the upper resin layer 25 corresponding to a forming position of the through via 29. The upper wiring 32 has a connecting portion 32A to which wires 43 are connected, and a connecting portion 32B to which the terminal 14 is connected. The upper wiring 32 is connected electrically to the semiconductor chip 12, the terminal 14, and the through via 29.

The upper wiring 33 is provided on a portion of the upper resin layer 25 corresponding to a forming position of the through via 31. The upper wiring 33 has a connecting portion 33A to which the chip parts 13 is connected, and a connecting portion 33B to which the terminal 15 is connected. The upper wiring 33 is connected electrically to the chip parts 13, the terminal 15, and the through via 31.

The upper wiring 34 is provided on a portion of the upper resin layer 25 corresponding to a forming position of the through via 30. The upper wiring 34 has a connecting portion 34A to which the wires 43 are connected, and a connecting portion 34B to which the chip parts 13 is connected. The upper wiring 34 is connected electrically to the semiconductor chip 12, the chip parts 13, and the through via 30. As the material of the upper wirings 32 to 34, a conductive metal can be employed and concretely Cu, for example, can be employed.

The protective film 35 is provided on the upper resin layer 25 to cover the upper wirings 32 to 34 in a state that the connecting portions 32A, 32B, 33A, 33B, 34A, 34B are exposed from this protective film 35. The protective film 35 is a film that protects the upper wirings 32 to 34. As the protective film 35, for example, solder resist can be employed.

The lower wiring 36 is provided to a portion of a lower surface 28A of the lower resin layer 28 corresponding to a forming position of the through via 29. The lower wiring 36 has a connecting portion 36A to which the external connection terminal 41 is connected. The lower wiring 36 is connected electrically to the through via 29 and the external connection terminal 41.

The lower wiring 37 is provided to a portion of the lower surface 28A of the lower resin layer 28 corresponding to a forming position of the through via 30. The lower wiring 37 has a connecting portion 37A to which the external connection terminal 41 is connected. The lower wiring 37 is connected electrically to the through via 30 and the external connection terminal 41.

The lower wiring 38 is provided to a portion of the lower surface 28A of the lower resin layer 28 corresponding to a forming position of the through via 31. The lower wiring 38 has a connecting portion 38A to which the external connection terminal 41 is connected. The lower wiring 38 is connected electrically to the through via 31 and the external connection terminal 41. As the material of the lower wirings 36 to 38, a conductive metal can be employed and concretely Cu, for example, can be employed.

The protective film 39 is provided on the lower surface 28A of the lower resin layer 28 to cover the lower wirings 36 to 38 in a state that the connecting portions 36A to 38A are exposed from the protective film 39. The protective film 39 is a film that covers the lower wirings 36 to 38. As the protective film 39, for example, solder resist can be employed.

The external connection terminal 41 is provided to the connecting portions 36A to 38A respectively. The external connection terminal 41 is the terminal that is connected electrically to a mounting substrate (not shown) such as the motherboard, or the like. As the external connection terminal 41, for example, a solder ball can be employed. In this case, the connecting portions 36A to 38A themselves may be used as the external connection terminal without provision of the external connection terminals 41.

The semiconductor chip 12 is provided on the upper resin layer 25. The semiconductor chip 12 is connected electrically to the connecting portions 32A, 34A of the upper wirings 32, 34 via the wires 43 (wire bonding connection). For example, when the semiconductor device 10 is constructed as a wireless module, the semiconductor chip (ASIC) having both functions of the CPU and the RF device can be employed as the semiconductor chip 12. In FIG. 1, the case where the semiconductor chip 12 is connected by the wire bonding is illustrated, but the semiconductor chip 12 may be flip-chip connected.

The chip parts 13 is provided on the first main surface of the wiring substrate 11 such that this chip parts can be connected electrically to the connecting portions 33A, 34B. The chip parts 13 is the parts such as a chip capacitor, a chip register, or the like, for example.

The terminal 14 is provided to the connecting portion 32B like a column. The terminal 14 is connected electrically to the through via 29 and via parts 44 of the inverted F-type antenna 20. Accordingly, the inverted F-type antenna 20 is connected electrically to the power-supply conductive layer 24.

The terminal 15 is provided to the connecting portion 33B like a column. The terminal 15 is connected electrically to the through via 31 and a via part 45 of the inverted F-type antenna 20. Accordingly, the inverted F-type antenna 20 is connected electrically to the ground conductive layer 27. As the material of the terminals 14, 15, a conductive metal can be employed and concretely Cu, for example, can be employed. The terminals 14, 15 can be constructed by a columnar block, a conductive metal deposited like a column by the plating method, or the like, for example.

The sealing resin 17 is provided on the first main surface of the wiring substrate 11 to cover the semiconductor chip 12, the chip parts 13, the terminals 14, 15, and the wires 43. Also, an opening portion 17A from which an upper surface of the terminal 14 is exposed, and an opening portion 17B from which an upper surface of the terminal 15 is exposed are formed in the sealing resin 17. Also, an upper surface 17C of the sealing resin 17 is formed as a flat surface. As the sealing resin 17, for example, a mold resin formed by the transfer molding method can be employed.

FIG. 2 is a view explaining the inverted F-type antenna.

The inverted F-type antenna 20 will be explained with reference to FIG. 1 and FIG. 2 hereunder.

The inverted F-type antenna 20 has the via parts 44, 45 and an antenna part 46. The via part 44 is formed in plural in the opening portion 17A formed in the sealing resin 17. One end portion of the via part 44 is connected to the terminal 14, and the other end portion is connected to the antenna part 46. The antenna part 46 is connected electrically to the power-supply conductive layer 24 via the via parts 44.

The via part 45 is provided in the opening portion 17B formed in the sealing resin 17. One end portion of the via part 45 is connected to the terminal 15, and the other end portion is connected to the antenna part 46. The antenna part 46 is connected electrically to the ground conductive layer 27 via the via part 45. The antenna part 46 is provided like a plate on positions of the sealing resin 17 corresponding to the forming positions of the via parts 44, 45. The antenna part 46 is connected electrically to the via parts 44, 45.

In this manner, since the inverted F-type antenna 20 is provided on the sealing resin 17, a size of the wiring substrate 11 along the surface direction can be reduced small rather than the case where the inverted F-type antenna 20 is provided on the first main surface of the wiring substrate 11, and thus the semiconductor device 10 can be reduced in size.

Also, since the antenna part 46 is provided on the sealing resin 17, a form of the antenna part 46 can be shaped into a desired pattern. As the material of the inverted F-type antenna 20, a conductive metal can be employed and concretely Cu, for example, can be employed.

The protective film 21 is provided on the sealing resin 17 to cover the antenna part 46. The protective film 21 is a film to protect the antenna part 46. As the protective film 21, for example, solder resist can be employed.

According to the semiconductor device of the present embodiment, the inverted F-type antenna 20 is provided on the sealing resin 17, the ground conductive layer 27 is provided in the inside of the wiring substrate 11, and the inverted F-type antenna 20 and the ground conductive layer 27 are connected electrically to each other. Therefore, a size of the wiring substrate 11 along the surface direction can be reduced small rather than the related-art semiconductor device where the ground conductive layer is provided on the first main surface of the wiring substrate 11. As a result, a size of the semiconductor device 10 can be reduced and also a cost of the semiconductor device 10 can be reduced.

Also, since the ground conductive layer 27 is provided in the inside of the wiring substrate 11, a layout of the wirings (e.g., the upper wirings 32, 33, etc.) formed on the wiring substrate 11 can be changed by utilizing the area of the wiring substrate 11 on the first main surface in which the ground conductive layer 27 is formed in the related art. As a result, flexibility of design can be increased.

In the present embodiment, the case where the power-supply conductive layer 24 is provided on the upper surface 23A of the core substrate 23 and also the ground conductive layer 27 is provided on the lower surface 23B of the core substrate 23 is explained as an example. In this case, the ground conductive layer 27 may be provided on the upper surface 23A of the core substrate 23 and also the power-supply conductive layer 24 may be provided on the lower surface 23B of the core substrate 23. The ground conductive layer 27 may be provided on the lower surface 28A of the lower resin layer 28 (a second main surface opposite to the first main surface of the wiring substrate 11). In this case, the same advantages as those of the semiconductor device in the present embodiment can also be achieved. Also, the ground conductive layer 27 may be provided on the second main surface of the wiring substrate 11 or in the inside of the wiring substrate 11.

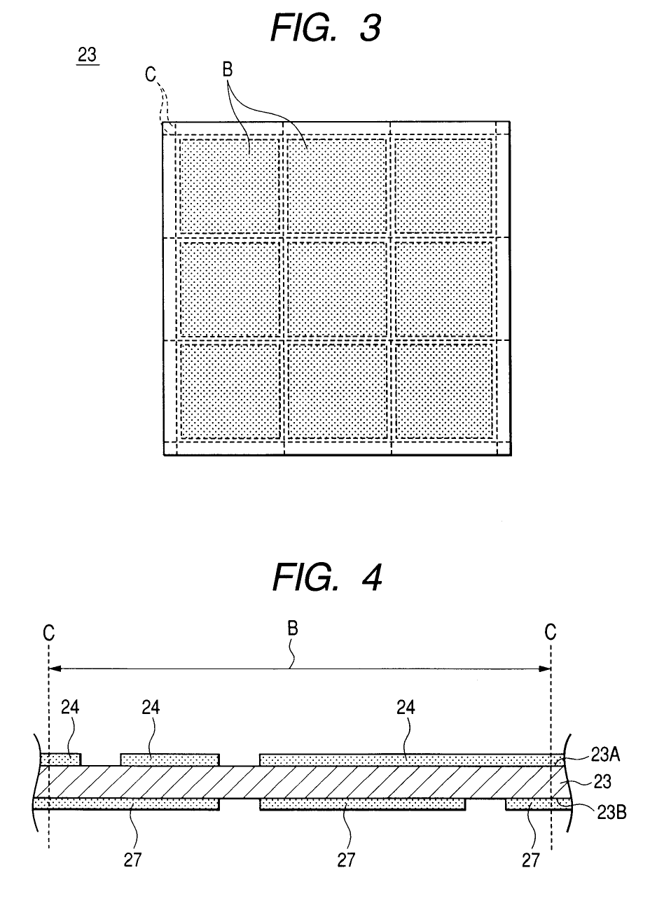

FIG. 3 is a plan view of the core substrate on which semiconductor devices of the present embodiment are formed. In FIG. 3, B shows a region in which the semiconductor device 10 is formed (referred to as a “semiconductor device formation region B” hereinafter), and C shows a position at which the dicing blade cuts the core substrate 23 (referred to as a “cutting position C” hereinafter).

Then, the core substrate 23 used in manufacturing the semiconductor device 10 will be explained with reference to FIG. 3 hereunder. The core substrate 23 has a plurality of semiconductor device formation regions B. The semiconductor devices 10 are formed on the core substrate 23 having a plurality of semiconductor device formation regions B. The core substrate 23 is cut along the cutting positions C after the structural bodies corresponding to the semiconductor devices 10 are formed, as descried above. Accordingly, the core substrate 23 is divided into individual semiconductor devices 10 and thus the semiconductor device 10 is manufactured.

FIG. 4 to FIG. 19 are views showing steps of manufacturing the semiconductor device according to the first embodiment. In FIG. 4 to FIG. 19, explanation will be made by taking as an example the case where the semiconductor device 10 is formed on the core substrate 23 shown foregoing FIG. 3. Also, in FIG. 4 to FIG. 19, the same reference symbols are affixed to the same constituent portions as those of the semiconductor device 10 shown in FIG. 1.

A method of manufacturing the semiconductor device according to the first embodiment will be explained with reference to FIG. 4 to FIG. 19 hereunder.

At first, as shown in FIG. 4, the power-supply conductive layer 24 is formed on the upper surface 23A of the core substrate 23 and also the ground conductive layer 27 is formed on the lower surface 23B of the core substrate 23. Concretely, for example, the core substrate 23 on both surfaces of which a copper foil is provided is prepared, and then the power-supply conductive layer 24 and the ground conductive layer 27 are formed by patterning the copper foil by means of the etching. As the core substrate 23, for example, a glass epoxy substrate, a ceramic substrate, or the like can be employed.

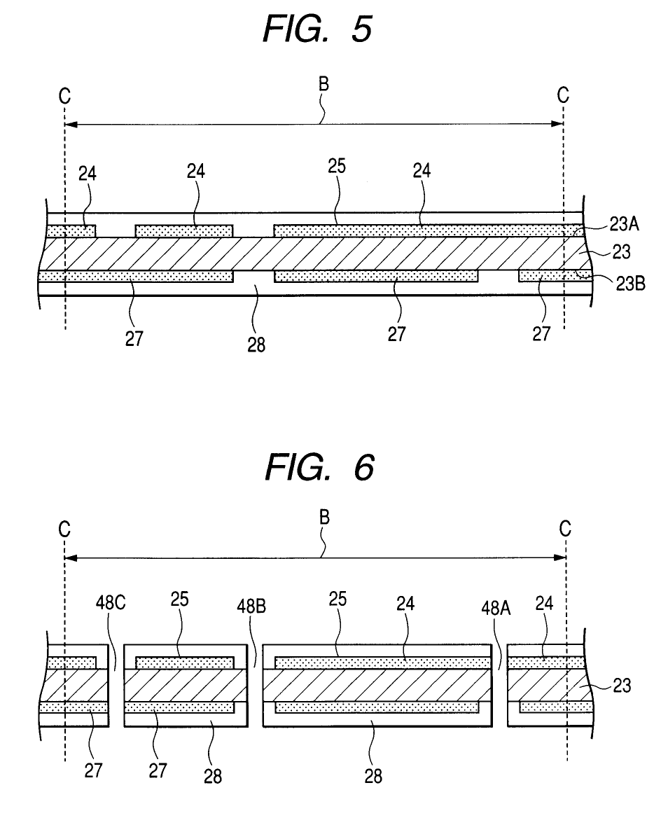

Then, as shown in FIG. 5, the upper resin layer 25 for covering the power-supply conductive layer 24 is formed on the upper surface 23A of the core substrate 23, and the lower resin layer 28 for covering the ground conductive layer 27 is formed on the lower surface 23B of the core substrate 23. Concretely, for example, the upper resin layer 25 and the lower resin layer 28 are formed on both surfaces of the structural body shown in FIG. 4 by coating an epoxy-based resin by virtue of the spin coating method, pasting an epoxy-based resin film, or the like.

Then, as shown in FIG. 6, a through hole 48A passing through the core substrate 23, the power-supply conductive layer 24, the upper resin layer 25, and the lower resin layer 28, a through hole 48B passing through the core substrate 23, the upper resin layer 25, and the lower resin layer 28, and a through hole 48C passing through the core substrate 23, the ground conductive layer 27, the upper resin layer 25, and the lower resin layer 28 are formed in the structural body shown in FIG. 5. The through hole 48A corresponds to the forming position of the through via 29, and also the through hole 48B corresponds to the forming position of the through via 30. Also, the through hole 48C corresponds to the forming position of the through via 31. The through holes 48A to 48C are formed by the drilling, the laser beam machining, or the like, for example.

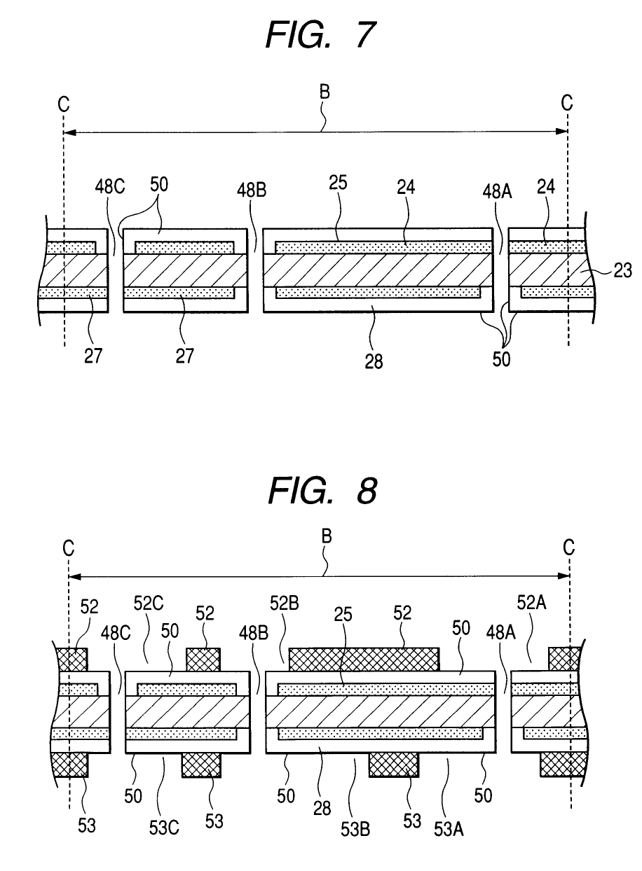

Then, as shown in FIG. 7, a seed layer 50 is formed on both surface of the structural body shown in FIG. 6 and the through holes 48A to 48C. Concretely, for example, a Cu layer is formed as the seed layer 50 by the electroless plating method.

Then, as shown in FIG. 8, a resist layer 52 having opening portions 52A to 52C to expose the seed layer 50 is formed on an upper surface of the structural body shown in FIG. 7, and a resist layer 53 having opening portions 53A to 53C to expose the seed layer 50 is formed on a lower surface of the structural body shown in FIG. 7. The opening portion 52A corresponds to the forming position of the upper wiring 32, the opening portion 52B corresponds to the forming position of the upper wiring 34, and the opening portion 52C corresponds to the forming position of the upper wiring 33. Also, the opening portion 53A corresponds to the forming position of the lower wiring 36, the opening portion 53B corresponds to the forming position of the lower wiring 37, and the opening portion 53C corresponds to the forming position of the lower wiring 38.

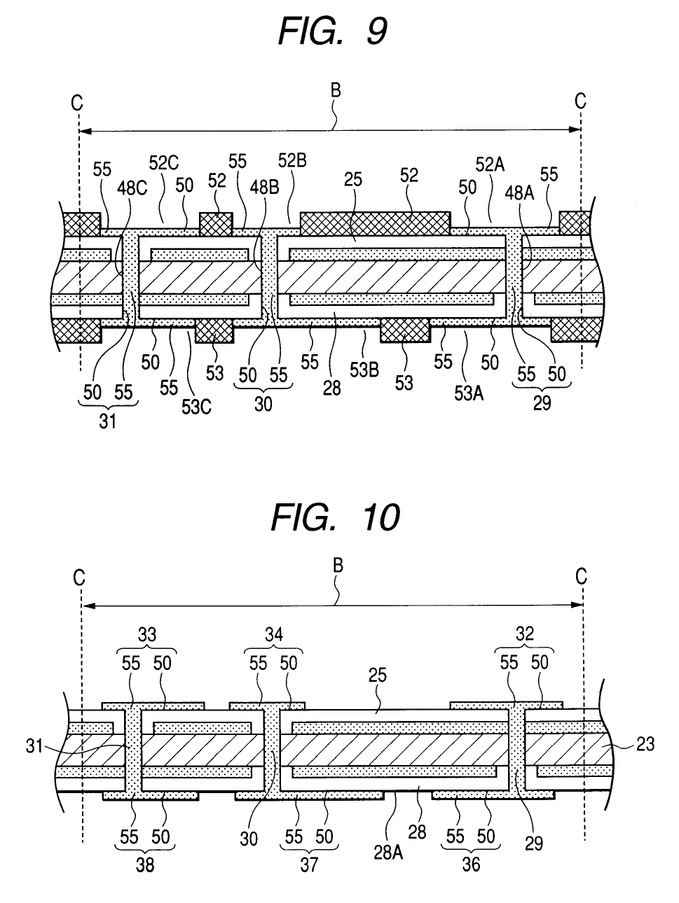

Then, as shown in FIG. 9, a conductive metal film 55 is deposited on the seed layer 50, which is exposed from the opening portions 52A to 52C, 53A to 53C and on the seed layer 50, which is formed on the through holes 48A to 48C, by the electroplating method using the seed layer 50 as a power feeding layer. Accordingly, the through vias 29 to 31 consisting of the seed layer 50 and the conductive metal film 55 respectively are formed in the through holes 48A to 48C. As the conductive metal film 55, for example, Cu can be employed.

Then, as shown in FIG. 10, the resist layers 52, 53 are removed and then the unnecessary seed layer 50 not covered with the conductive metal film 55 is removed. Accordingly, the upper wirings 32 to 34 consisting of the seed layer 50 and the conductive metal film 55 respectively are formed on the upper resin layer 25, and the lower wirings 36 to 38 consisting of the seed layer 50 and the conductive metal film 55 respectively are formed on the lower surface 28A of the lower resin layer 28.

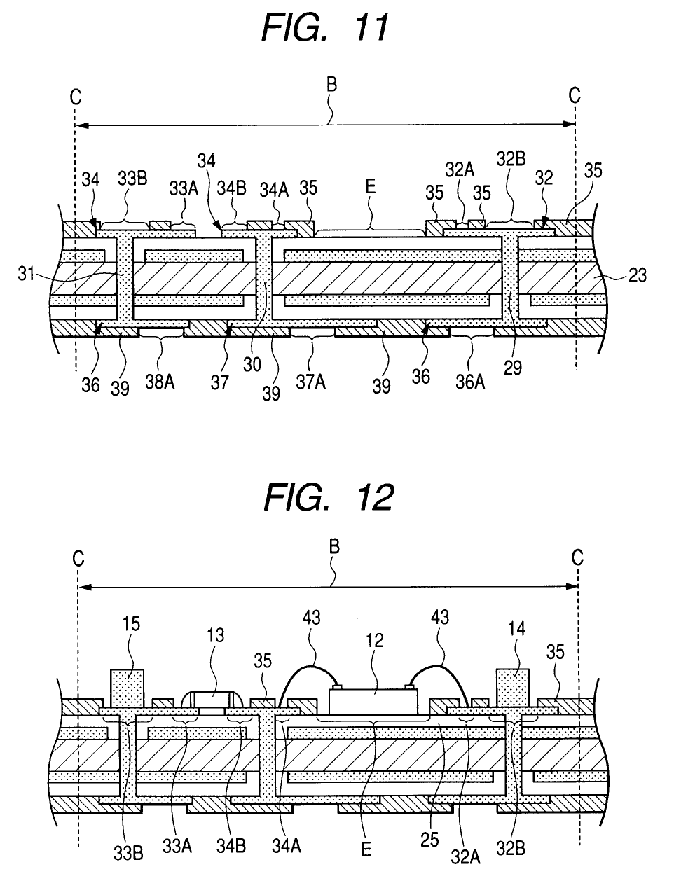

Then, as shown in FIG. 11, the protective film 35 from which the connecting portions 32A, 32B, 33A, 33B, 34A, 34B and an area E in which the semiconductor chip 12 is mounted are exposed is formed on an upper surface of the structural body shown in FIG. 10, and the protective film 39 from which the connecting portions 36A, 37A, 38A are exposed is formed on a lower surface of the structural body shown in FIG. 10. Accordingly, the structural body corresponding to a structure of the wiring substrate 11 is formed in the semiconductor device formation region B of the core substrate 23. As the protective films 35, 39, for example, the solder resist can be employed. When the solder resist is employed as the protective films 35, 39, such protective films 35, 39 are formed by the screen printing using a resist ink or the photographic method using a film, for example.

Then, as shown in FIG. 12, the semiconductor chip 12, the chip parts 13, and the terminals 14, 15 are provided on an upper surface of the structural body shown in FIG. 11. Concretely, for example, the semiconductor chip 12 is bonded to the upper resin layer 25 corresponding to the area E, the semiconductor chip 12 and the connecting portions 32A, 34A are connected electrically to each other via the wires 43, electrodes (not shown) of the chip parts 13 and the connecting portions 33A, 34B are connected by the solder, and the terminals 14, 15 and the connecting portion 32B or the connecting portion 33B are connected via the solder. As the terminals 14, 15, for example, a block-like terminal can be employed. Also, as the material of the terminals 14, 15, a conductive metal can be employed and concretely Cu, for example, can be employed. In this case, the semiconductor chip 12 may be flip-chip bonded.

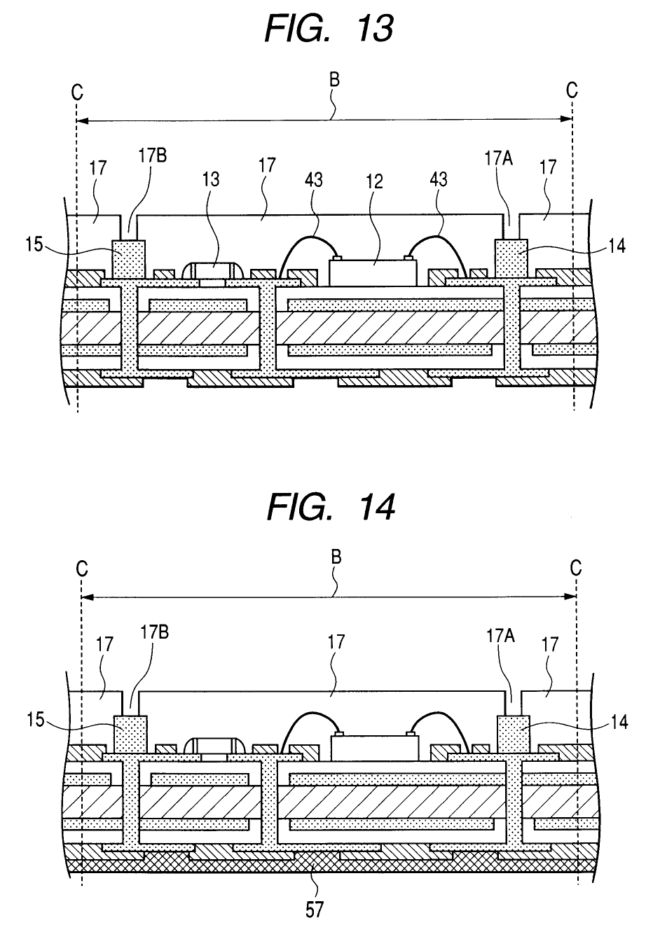

Then, as shown in FIG. 13, the sealing resin 17 is formed to cover an upper surface of the structural body shown in FIG. 12, and then the opening portion 17A to expose an upper surface of the terminal 14 and the opening portion 17B to expose an upper surface of the terminal 15 are formed in the sealing resin 17. The sealing resin 17 is formed by the transfer molding method, for example. Also, the opening portions 17A, 17B are formed by the laser beam machining, for example.

Then, as shown in FIG. 14, a resist layer 57 is formed to cover the lower surface side of the structural body shown in FIG. 13. Then, as shown in FIG. 15, a seed layer 58 is formed to cover the opening portions 17A, 17B and the upper surface of the sealing resin 17, and then a resist layer 59 having an opening portion 59A is formed on the seed layer 58. The opening portion 59A is an opening portion to expose a portion of the seed layer 58 corresponding to the forming position of the antenna part 46. Concretely, for example, a Cu layer is formed as the seed layer 58 by the electroless plating method, and then the resist layer 59 having the opening portion 59A is formed on the seed layer 58.

Then, as shown in FIG. 16, a conductive metal film 61 is deposited on the seed layer 58, which is exposed from the opening portion 59A, by the electroplating method using the seed layer 58 as a power feeding layer. Accordingly, the via parts 44, 45 consisting of the seed layer 58 and the conductive metal film 61 are formed in the opening portions 17A, 17B. As the conductive metal film 61, for example, Cu can be employed.

Then, as shown in FIG. 17, the resist layers 57, 59 are removed and then the unnecessary seed layer 58 not covered with the conductive metal film 61 is removed. Accordingly, the antenna part 46 consisting of the seed layer 58 and the conductive metal film 61 is formed.

Then, as shown in FIG. 18, the protective film 21 for covering the antenna part 46 is formed on the sealing resin 17, and then the external connecting terminal 41 is formed on the connecting portions 36A to 38A. Accordingly, the structural body corresponding to the structure of the semiconductor device 10 is formed in the semiconductor device formation region B of the core substrate 23. As the protective film 21, for example, solder resist can be employed. When the solder resist is employed as the protective film 21, for example, the protective film 21 can be formed by the screen printing method using the resist ink. As the external connecting terminals 41, for example, the solder ball can be employed.

Then, as shown in FIG. 19, the structural body formed in the semiconductor device formation region B is divided into individual pieces by cutting the core substrate 23 along the cutting positions C, and thus a plurality of semiconductor devices 10 are manufactured. Also, for example, the dicing blade can be employed to cut the core substrate 23.

### Second Embodiment

FIG. 20 is a sectional view of a semiconductor device according to a second embodiment of the present invention.

A semiconductor device 70 according to the second embodiment of the present invention will be explained with reference to FIG. 20 hereunder. In FIG. 20, the same reference symbols are affixed to the same constituent portions as the semiconductor device 10 of the first embodiment, and their explanation will be omitted herein.

The semiconductor device 70 is constructed similarly to the semiconductor device 10 according to the first embodiment except that vias 71, 72, pads 74, a ground conductive layer 75, and an insulating layer 77 are provided to the structure of the semiconductor device 10.

The via 71 is provided to the opening portion 17A in the sealing resin 17. The via 71 is connected to the terminal 14 at its lower end portion, and is connected to the pad 74 at its upper end portion. The via 72 is connected to the terminal 15 at its lower end portion, and is connected to the ground conductive layer 75 at its upper end portion. As the material of the vias 71, 72, a conductive metal can be employed and concretely Cu, for example, can be employed.

The pad 74 is provided on the upper surface 17C of the sealing resin 17 corresponding to the forming position of the via 71. The pad 74 connects electrically the via 71 and the via part 44. As the material of the pad 74, a conductive metal can be employed and concretely Cu, for example, can be employed.

The ground conductive layer 75 is provided on the upper surface 17C of the sealing resin 17 corresponding to the forming position of the via 72. The ground conductive layer 75 is the ground conductive layer 75 that is connected electrically to the inverted F-type antenna 20. As the material of the ground conductive layer 75, a conductive metal can be employed and concretely Cu, for example, can be employed.

The insulating layer 77 is provided on the upper surface 17C of the sealing resin 17 to cover the pad 74 and the ground conductive layer 75. An opening portion 77A for exposing an upper surface of the pad 74, and an opening portion 77B for exposing an upper surface of the ground conductive layer 75 are formed in the insulating layer 77. As the insulating layer 77, for example, an epoxy-based resin can be employed.

The via part 44 is provided in the opening portion 77A. The via part 44 is connected electrically to the pad 74 and the antenna part 46. The via part 45 is provided in the opening portion 77B. The via part 45 is connected electrically to the ground conductive layer 75 and the antenna part 46.

The antenna part 46 is provided on the insulating layer 77. The antenna part 46 is connected electrically to the via parts 44, 45. The protective film 21 is provided on the insulating layer 77 to cover the antenna part 46.

In this manner, the inverted F-type antenna 20 and the ground conductive layer 75 may be connected electrically by providing the inverted F-type antenna 20 over the sealing resin 17 and also providing separately the ground conductive layer 75 on the sealing resin 17. The semiconductor device 70 constructed in this manner in the second embodiment can also achieve the similar advantages as the semiconductor device 10 of the first embodiment.

Also, according to the semiconductor devices 70 of the present embodiment, since the ground conductive layer 75 connected to the inverted F-type antenna 20 is provided separately on the sealing resin 17, there in no necessary to provide the ground conductive layer 27 with a wide area on the lower surface 23B of the core substrate 23. Therefore, the wiring pattern can be provided in place of the ground conductive layer 27. In addition, when the ground conductive layer 27 is not needed in the wiring substrate 11, it is not needed to provide the ground conductive layer 27 and the lower resin layer 28. Therefore, the semiconductor device 70 can be reduced in size by thinning the wiring substrate 11.

Also, the semiconductor device 70 of the present embodiment can be manufactured by the same approach as the manufacturing steps of the semiconductor device 10 in the first embodiment.

Here, a resin layer acting as a glue layer between the sealing resin 17, the pad 74, and the ground conductive layer 75 may be provided on the upper surface 17C of the sealing resin 17.

The preferred embodiments of the present invention are described in detail. But the present invention is not limited to the particular embodiments, and various variations/modifications can be applied within a scope of the gist of the present invention set forth in claims. Also, the present invention can be applied to the antenna except the inverted F-type antenna 20, e.g., the patch antenna. The patch antenna is not directly connected to the ground conductive layer, but such patch antenna must be arranged under the antenna part for the reason of structure. Therefore, in the semiconductor device in which the structures of the semiconductor devices 10, 70 according to the first and second embodiments are applied and the patch antenna is provided instead of the inverted F-type antenna 20, a miniaturization of the semiconductor device can also be achieved.

The present invention can be applied to a semiconductor device capable of achieving a size reduction and also a cost reduction.

What is claimed is:

1. A semiconductor device, comprising:
a wiring substrate;
an electronic parts provided on a first main surface of the wiring substrate and connected electrically to the wiring substrate;
a passive circuit; and
a sealing resin for sealing the electronic parts,
wherein the passive circuit is provided on the sealing resin, and a ground conductive layer is provided in an inside of the wiring substrate or on a second main surface on an opposite side to the first main surface of the wiring substrate.

2. A semiconductor device comprising:
a wiring substrate;
an electronic parts provided on a first main surface of the wiring substrate and connected electrically to the wiring substrate;
a passive circuit; and
a sealing resin for sealing the electronic parts,
wherein a ground conductive layer is provided on the sealing resin, an insulating layer is provided on the ground conductive layer, and the passive circuit is provided on the insulating layer.

3. A semiconductor device according to claim 1, wherein the wiring substrate further has a power-supply conductive layer in the inside of the wiring substrate, and
the passive circuit is an inverted F-type antenna connected electrically to the ground conductive layer and the power-supply conductive layer.

4. A semiconductor device according to claim 2, wherein the wiring substrate further has a power-supply conductive layer in an inside of the wiring substrate, and
the passive circuit is an inverted F-type antenna connected electrically to the ground conductive layer and the power-supply conductive layer.
